(19) United States
(12) Patent Application Publication
(10) Pub. No.: US 2025/0076156 A1
(43) Pub. Date: Mar. 6, 2025

(54) THERMAL-MECHANICAL TESTING DEVICE FOR PLATFORM INTEGRATION

(71) Applicant: SK Hynix NAND Product Solutions Corp. (dba Solidigm), Rancho Cordova, CA (US)

(72) Inventors: Hardeep Singh, Vancouver (CA); Leo Craft, Shingle Springs, CA (US)

(21) Appl. No.: 18/239,428

(22) Filed: Aug. 29, 2023

(51) Int. Cl. G01M 99/00; G01K 1/02; G01P 5/14; H05K 1/02

(52) U.S. Cl. CPC G01M 99/002; G01K 1/026; G01P 5/14; H05K 1/0266; H05K 2201/10151

(57) ABSTRACT

A testing device, related method for using the testing device and a production device arranged based on a predicted ambient temperature determined using the testing device, the testing device including a circuitry of a first form factor that corresponds to a second form factor of the production device. Circuitry includes heat-generating electrical components to simulate thermal generation of the production device. The circuitry also includes sensors to measure at least one characteristic of airflow of the testing device and at least one temperature of the testing device. The sensors include a first sensor disposed upstream of the airflow, and a second sensor disposed downstream of the airflow. The circuitry also includes processing circuitry to receive sensor data from the sensors indicative the characteristics of airflow and the temperatures of the testing device, and to determine a predicted ambient temperature proximate to the production device based on the sensor data.

### TECHNICAL FIELD

The present disclosure is directed to a testing device to optimize thermal distribution of a production device emulated by the testing device.

### SUMMARY

In accordance with the present disclosure, testing devices and methods for using testing devices are provided to diagnose or design production devices emulated by the testing device. The testing device may include circuitry of a form factor which matches or corresponds to that of a production device. The production device may be any functional device that may be replaced by the testing device. For example, a production device may be a storage device (e.g., a solid-state drive (SSD) device). The circuitry may include heat-generating electrical components to simulate thermal generation of the production device and sensors to measure characteristics of the airflow of the testing device and measure temperatures of the testing device. The sensors may include temperature sensors and airflow sensors, where at least a first sensor is mounted onto the circuitry upstream of the airflow and a second sensor mounted onto the circuitry downstream of the airflow. The circuitry also includes processing circuitry to receive sensor data from the sensors and determine a predicted ambient temperature proximate to the production device based on the sensor data.

The testing device and methods disclosed herein are provided to optimize thermal distribution of production devices emulated by the testing device. The optimized thermal distribution ensures that the production device may operate at certain work rates and therefore generate a certain amount of heat without thermal throttling or requiring an increase in airflow between the production devices. In some embodiments, testing device includes an enclosure around the circuitry, the enclosure including a top cover and a bottom cover, each of a thermally-conductive material. In some embodiments, thermal interface material (TIM) layers are arranged between the circuitry and each of the top cover and the bottom cover.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, and/or characteristic included in at least one implementation. Thus, phrases such as “in one embodiment” or “in an alternate embodiment” appearing herein describe various embodiments and implementations, and do not necessarily all refer to the same embodiment. However, they are also not necessarily mutually exclusive.

FIG. 1 shows an illustrative perspective view diagram through the top cover of the testing device, in accordance with some embodiments of the present disclosure;

FIG. 2 shows an illustrative perspective view diagram through the bottom cover of the testing device, similar to that of FIG. 1, in accordance with some embodiments of the present disclosure;

FIG. 3 shows an illustrative depiction of a sensor used to determine at least one air flow characteristic of airflow of the testing device, in accordance with some embodiments of the present disclosure;

FIG. 4 shows an illustrative cross-sectional diagram of a testing device, in accordance with some embodiments of the present disclosure;

FIG. 5 shows an illustrative exploded view diagram of a testing device, in accordance with some embodiments of the present disclosure;

FIG. 6 shows a flowchart of illustrative steps for using a testing device, in accordance with some embodiments of the present disclosure; and

FIG. 7 shows a flowchart of illustrative steps of a subprocess for determining a predicted ambient temperature proximate to the production device based on the sensor data, in accordance with some embodiments of the present disclosure.

### DETAILED DESCRIPTION

In accordance with the present disclosure, testing devices and methods for using thereof are provided for optimizing thermal distribution of production devices (e.g., solid-state drives (SSDs)). The testing device includes circuitry of a form factor which matches or corresponds to that of the production device. The circuitry of the testing device includes heat-generating electrical components to emulate the thermal generation of electrical components of the production device while in operation. Sensors are also mounted onto the circuitry to measure characteristics of the airflow of the testing device and temperatures of the testing device. In some embodiments, the airflow is provided by at least one fan disposed proximate to the testing device, wherein the airflow travels along the testing device to promote thermal dissipation from the testing device to the ambient air. The sensors may include temperature sensors and airflow sensors, where at least a first sensor is mounted onto the circuitry upstream of the airflow and a second sensor mounted onto the circuitry downstream of the airflow. The circuitry also includes processing circuitry to receive sensor data from the sensors and determine a predicted ambient temperature proximate to the production device based on the sensor data.

The testing device disclosed herein may be enclosed by any suitable packaging/enclosure of the circuitry including electrical components mounted onto the circuitry. The circuitry or the packaging/enclosure surrounding the circuitry may be of any suitable form factor which corresponds to that of the production device which the testing device emulates. For example, the testing device may be surrounded by an enclosure with a top cover and bottom cover, each of which are thermally-conductive in order to promote heat dissipation from the circuitry of the testing device to the ambient air proximate to the testing device. The circuitry may include one or more integrated circuits or dies. In some embodiments, the circuitry itself is a printed circuit board (PCB) with conductive traces integrated within layers of the PCB. Any heat generated by the circuitry may refer to thermal output of heat-generating electrical components of the circuitry (e.g., high-performance integrated circuit chips or cores).

In some embodiments, circuitry includes processing circuitry, which may include a processor or processing unit, implemented by hardware, software, or a combination thereof. The processing circuitry receives sensor data indicative of characteristics of airflow and temperature of the testing device from sensors (e.g., airflow sensors and temperature sensors). The processing circuitry is to receive sensor data from each of the airflow sensors and the temperature sensors. Processing circuitry then determines a predicted ambient temperature proximate to the production device emulated by the testing device based on the sensor data. In some embodiments circuitry is of a first form factor which corresponds to a second form factor of the production device which the testing device emulates. The form factor of circuitry may be defined as the footprint or three-dimensional (3-D) form factor for heat production. In some embodiments, each component of the production device emulated by testing device is replicated in testing device, where the arrangement and location of each respective component are the same.

The temperature sensors are mounted on and electrically coupled to circuitry, each temperature sensor measuring a respective temperature of the testing device at different positions of the testing device. There may be more than two temperature sensors mounted onto circuitry to provide a greater granularity of temperature sensor data for the temperature of the testing device. In some embodiments, processing circuitry processes the temperature sensor data by determining a difference in temperature of the testing device from a first side of the testing device upstream of the airflow and a second side of the testing device downstream of the airflow.

Air flow sensors are mounted to the circuitry and communicatively coupled to processing circuitry via the circuitry. In some embodiments, there are at least a first air flow sensor disposed upstream of the airflow and a second air flow sensor disposed downstream of the airflow in order to determine certain characteristics of the airflow (e.g., fluid pressure drop along the testing device). In some embodiments, the air flow sensors measure at least one characteristic of airflow, including any one of: fluid pressure, airflow velocity, or airflow flux rate.

The heat-generating electrical components may be any suitable high-performance electrical component (e.g., an integrated circuit device, such as an application-specific integrated circuit (ASIC) device). In some embodiments, the circuitry includes a printed circuit board (PCB), which may include multiple dielectric layers, on which the electrical components may be mounted. In some embodiments where circuitry are enclosed by a top cover and bottom cover of an enclosure, a TIM may be positioned between the heat-generating electrical components of the circuitry and at least one of the thermally-conductive covers (e.g., the top cover and bottom cover).

For purposes of brevity and clarity, the features of the disclosure described herein are in the context of a package with an external layer, interface layer, thermal spreader layer and circuitry. However, the principles of the present disclosure may be applied to any other suitable context in which an enclosure for the circuitry is used.

In particular, the present disclosure provides testing devices and methods for using thereof, where the testing device emulates a production device to optimize the thermal distribution of the production device. The testing device and methods for using thereof provided to diagnose or design production devices emulated by the testing device. This ensures that the production device may operate at certain work rates and generate a certain amount of heat without thermal throttling or requiring an increase in airflow between the production devices.

In some embodiments, the circuitry of the testing device may include any suitable processing circuitry, which may include any suitable processing chip (e.g., an application-specific integrated circuit (ASIC) chip) or processing core.

In some embodiments the testing device and methods for using the testing device of the present disclosure may include circuitry which functions as a storage device system (e.g., an SSD storage system), which includes a storage device such as a solid-state drive device.

An SSD is a data storage device that uses integrated circuit assemblies as memory to store data persistently. SSDs have no moving mechanical components, and this feature distinguishes SSDs from traditional electromechanical magnetic disks, such as, hard disk drives (HDDs) or floppy disks, which contain spinning disks and movable read/write heads. Compared to electromechanical disks, SSDs are typically more resistant to physical shock, run silently, have lower access time, and less latency.

Many types of SSDs use NAND-based flash memory which retain data without power and include a type of non-volatile storage technology. Quality of Service (QOS) of an SSD may be related to the predictability of low latency and consistency of high input/output operations per second (IOPS) while servicing read/write input/output (I/O) workloads. This means that the latency or the I/O command completion time needs to be within a specified range without having unexpected outliers. Throughput or I/O rate may also need to be tightly regulated without causing sudden drops in performance level.

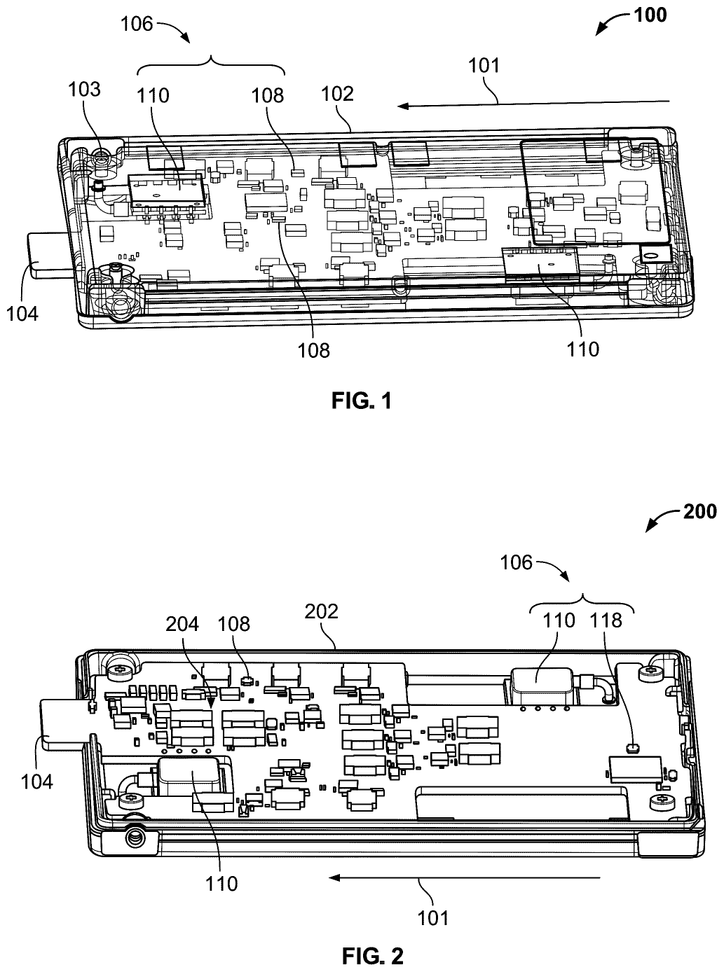

The subject matter of this disclosure may be better understood by reference to FIGS. 1-7.

FIG. 1 shows an illustrative perspective view diagram through the top cover of the testing device 100, in accordance with some embodiments of the present disclosure. In some embodiments, as illustrated in FIG. 1, testing device 100 includes a top cover 102 which encloses circuitry 104. Top cover 102 may include access points 103 to the airflow 101 or ambient air traveling along or disposed proximate to the top cover 102. Circuitry 104 includes sensors 106 mounted onto and communicatively coupled to circuitry 104, the sensors including at least a first sensor, which is positioned upstream of airflow 101, and a second sensor positioned downstream of airflow 101. In some embodiments, each of the first sensor and the second sensor is an air flow sensor (e.g., air flow sensor 110). Sensors 106 also includes temperature sensors 108, which are positioned in various positions along circuitry 104. In some embodiments, testing device 100 may not include the top cover 102 depending on the device of which testing device 100 is emulating. Although circuitry 104 is illustrated as a printed circuit board (PCB), it is understood that circuitry 104 may be any form of circuitry (e.g., flex circuitry, PCB) which includes the plurality of sensors and heat-generating electrical components. In some embodiments, circuitry 104 includes at least one electrical component which generates heat while testing device 100 is in operation. In some embodiments, testing device 100 includes a thermal interface material (TIM) layer (not shown) disposed between and in thermal contact with the top cover 102 and circuitry 104. In some embodiments, the TIM layer improves thermal transfer from the heat-generating electrical components of circuitry 104 to the top cover 102.

In some embodiments, top cover 102 is thermally-conductive to promote heat dissipation from the top cover 102 of testing device 100 to the air proximate to testing device 100. In some embodiments, airflow 101 travels along the testing device 100, where airflow 101 may promote heat dissipation from the top cover 102 to the ambient air proximate to the testing device 100. In some embodiments, the top cover 102 is a part of an enclosure which surrounds circuitry 104, the enclosure of a form factor which matches that of the production device of which the testing device emulates. In some embodiments, the testing device 100 does not include top cover 102 and circuitry 104 is exposed to ambient air proximate the testing device and airflow 101. The testing device 100 may be positioned proximate to at least fan which provides airflow 101 from the upstream to the downstream. In some embodiments, the testing device 100 is positioned in a rack enclosure with productions devices which the testing device emulates 100. In such embodiments, the testing device 100 and each production device are positioned parallel to each other such that airflow 101 formed by the at least one fan flows along spaces formed between each of the testing device and production devices.

In some embodiments, circuitry 104 includes processing circuitry. Processing circuitry may include a processor or processing unit, implemented by hardware, software, or a combination thereof. The processing circuitry is to receive sensor data from sensors 106 indicative of the at least one characteristic of airflow 101 of the testing device 100 and temperature of the testing device 100. The processing circuitry is to receive sensor data from each of the air flow sensors 110 and each of the temperature sensors 108. Processing circuitry then determines a predicted ambient temperature proximate to the production device emulated by the testing device 100 based on the sensor data. In some embodiments, electrical pads or padded through-holes are arranged throughout circuitry 104 to receive and electrically couple to pins or pads of sensors 106. In some embodiments, circuitry 104 includes electrical components or sensors mounted on each side of circuitry 104 (e.g., each side of the PCB). In some embodiments circuitry 104 is of a first form factor which corresponds to a second form factor of the production device which the testing device emulates. The form factor of circuitry 104 may be defined as the footprint or three-dimensional (3-D) form factor for heat production. In some embodiments, each component of the production device emulated by testing device 100 is replicated in testing device 100, where the arrangement and location of each respective component are the same.

Testing device 100 includes temperature sensors 108, which are mounted on and electrically coupled to circuitry 104. Each temperature sensor 108 measure a respective temperature of the testing device 100 at different positions of the testing device 100. In some embodiments, the testing device includes at least two temperature sensors 108 to measure a first temperature of the testing device 100 upstream of airflow 101, and a second temperature of the testing device 100 downstream of airflow 101. In some embodiments, there may be more than two temperature sensors 108 mounted onto circuitry 104 to provide a greater granularity of sensor data for the temperature of the testing device 100. Each temperature sensor 108 provides temperature data of testing device 100 to processing circuitry in part to determine a predicted ambient temperature proximate to the production device emulated by the testing device 100. In some embodiments, processing circuitry processes the sensor data by determining a difference in temperature of the testing device from a first side of the testing device 100 upstream of airflow 101 and a second side of the testing device 100 downstream of airflow 101.

Air flow sensors 110 are communicatively coupled to processing circuitry via circuitry 104. In some embodiments, there are at least a first air flow sensor disposed upstream of airflow 101 and a second air flow sensor disposed downstream of airflow 101. In some embodiments, the air flow sensors 110 measure at least one characteristic of airflow 101, including any one of: fluid pressure drop along the testing device, airflow velocity, or airflow flux rate.

Once the processing circuitry of circuitry 104 receives sensor data from the sensors 106 the processing circuitry determines a predicted ambient temperature proximate to the production device based on the sensor data. In some embodiments, sensor data includes air flow sensor data and the temperature sensor data. In some embodiments, the processing circuitry calculates a mean temperature of the received temperature sensor data. In other embodiments, the processing circuitry determines a maximum temperature value among the received temperature sensor data. The processing circuitry may use the airflow sensor data to calculate processed data indicative of the at least one characteristic of the airflow 101 of the testing device 100. The processing circuitry is then to determine the predicted ambient temperature proximate to a production device under the same conditions of the testing device. Processing circuitry may determine the predicted ambient temperature proximate to the production device based on airflow velocity and any one of: the temperature of the testing device 100, fluid pressure drop along the testing device, and airflow flux rate. In some embodiments, the processing circuitry determines the predicted ambient temperature proximate to the production device based on previous iterations of data collection.

In some embodiments, testing device 100 may include other sensors, including accelerometers and strain gauges to determine sensor data indicative of mechanical stress of the testing device 100. This additional sensor data, which is received by the processing circuitry of circuitry 104, enables the processing circuitry to determine an expected amount of mechanical stress applied to the production devices emulated by the testing device 100. The collection and determination of mechanical stress data on the testing device 100 may result in design modifications or changes to the production device. In addition, the testing device 100 may be used as a diagnostic tool to determine mechanical stress applied on production devices in operation. Testing device 100 may include at least one accelerometer mounted onto circuitry 104 to determine movements, jerks, acceleration in any three-dimensional direction. The strain gauges may be mounted onto circuitry 104 to determine the strain on circuitry 104. Mechanical strain on testing device 100 may cause failures in operation or damage to the testing device 100.

It will be understood that, while testing device 100 depicts an embodiment in which circuitry 104 is encapsulated by the top cover 102 in accordance with the present disclosure, any other suitable housing may be implemented in a similar manner.

For purposes of clarity and brevity, and not by way of limitation, the present disclosure is provided in the context of a testing device 100 and methods thereof, which provide the features and functionalities disclosed herein. The testing device 100 may be used to optimize at least one electrical device, for example, a server device or storage device of a respective form factor. In some embodiments, testing device 100 may also be used as a post-fabrication, validation device for production devices, or as a thermal cooling diagnostic device for production devices.

FIG. 2 shows an illustrative perspective view diagram through the bottom cover 202 of the testing device 200, similar to testing device 100 of FIG. 1, in accordance with some embodiments of the present disclosure. In some embodiments, as illustrated in FIG. 2, testing device 200 includes a bottom cover 202 which encloses circuitry 104. Similarly depicted in FIG. 1, testing device 200 includes sensors 106 mounted onto and communicatively coupled to this bottom side of circuitry 104, where the bottom side is defined as the side of circuitry 104 facing bottom cover 202. In some embodiments, circuitry is enclosed by an enclosure which includes the top cover 102 and bottom cover 202. Temperature sensors 108 are disposed in various positions along the circuitry 104. In some embodiments, testing device 200 may not include the bottom cover 202, exposing circuitry 104 to the ambient air and airflow 101.

In some embodiments, circuitry 104 includes at least one heat-generating electrical component 204 which generates heat while testing device 200 is in operation. The heat-generating electrical components 204 are used to emulate the heat generation of the production device of which testing device 200 is used to optimize. In some embodiments, the heat-generating electrical components 204 include at least one resistor to function as a heat-generating load as current passes through each respective resistor. In some embodiments, the heat generated by the heat-generating electrical components 204 may be configured by circuitry 104. For example, processing circuitry of circuitry 104 may cause a change in the current that is provided to the heat-generating electrical components 204 to alter the heat generated by testing device 200. When more current is provided to the heat-generating electrical components 204 (e.g., resistors) the heat-generating electrical components 204 generate more heat. Therefore, for a respective form factor of the devices in which testing device 200 emulates there is a range of applications for which testing device 200 may be used.

In some embodiments, testing device 200 includes a thermal interface material (TIM) layer (not shown) disposed between and in thermal contact with the bottom cover 202 and the heat-generating electrical components 204. In some embodiments, the TIM layer improves thermal transfer from the heat-generating electrical components 204 of circuitry 104 to the bottom cover 202. In some embodiments, the bottom cover 202 is thermally-conductive to promote further heat dissipation.

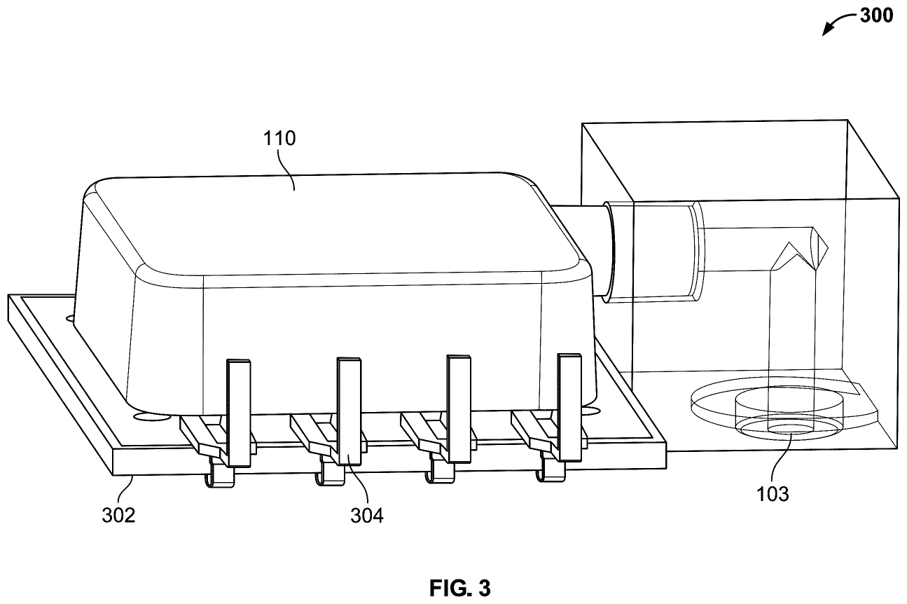

FIG. 3 shows an illustrative depiction of a sensor system 300 used to determine at least one air flow characteristic of airflow traveling along the testing device, in accordance with some embodiments of the present disclosure. In some embodiments, the sensor system 300 includes a breakout printed circuit board (PCB) 302, which may be a part of circuitry 104 of the testing device (e.g., testing device 100). In some embodiments, the breakout PCB 302 is communicatively coupled to processing circuitry for the processing circuitry to receive measured sensor data indicative of at least one characteristic of airflow of the testing device. In some embodiments, sensor 110 includes pins 304 which electrically couple to the breakout PCB 302. In some embodiments, sensor 110 is mounted onto breakout PCB 302 by a solder mount or any other suitable mounting to breakout PCB 302. In addition, sensor 110 includes access to access point 103 in order to measure at least one characteristic of airflow (e.g., airflow 101) of the testing device. In some embodiments, the access point 103 may enable sensor 110 to access ambient air or the airflow of the testing device (e.g., airflow 101), which may be external to an enclosure surrounding circuitry 104. In some embodiments, sensor 110 collects data for the airflow traveling along the testing device or ambient air data. In some embodiments, sensor 110 collects data indicative of at least one of: fluid pressure drop along the testing device, airflow velocity, or airflow flux rate.

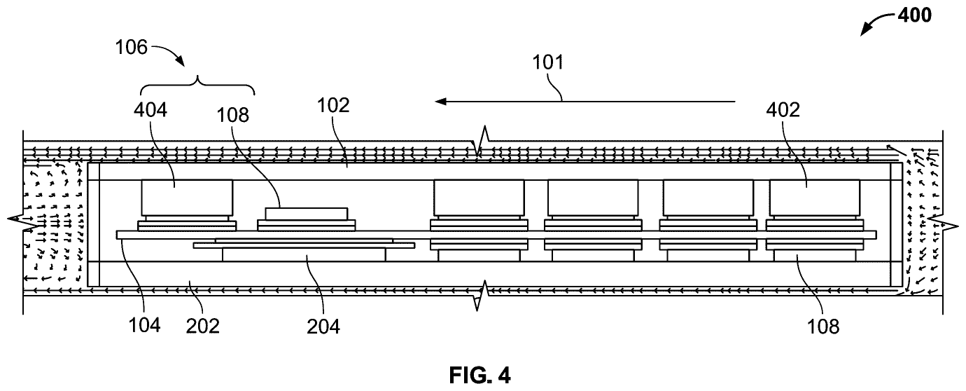

FIG. 4 shows an illustrative cross-sectional diagram of a testing device 400, including circuitry 104 enclosed by top cover 102 and bottom cover 202. In some embodiments, testing device 400 includes sensors 106 mounted onto circuitry 104. Testing device 400 also includes heat-generating electrical components 204 to simulate the heat generated by components of a production device when in operation. As seen in previous figures, sensors 106 include at least one temperature sensor 108 to determine temperature of the testing device 400 and at least two air flow sensors (e.g., first airflow sensor 402 and second airflow sensor 404) to determine at least one air flow characteristic of airflow 101. In some embodiments, the first airflow sensor 402 is disposed upstream of airflow 101 and the second airflow sensor 404 is disposed downstream of airflow 101. In some embodiments, processing circuitry of circuitry 104 receives sensor data from each of the temperature sensors 108 and airflow sensors (e.g., first airflow sensor 402 and second airflow sensor 404). In some embodiments, processing circuitry of the circuitry 104 determines the predicted ambient temperature proximate to the production device the testing device emulates based on air flow sensor data and the temperature sensor data. In some embodiments, processing circuitry calculates ambient air temperature proximate to the testing device. In some embodiments, the processing circuitry calculates a mean temperature of the received temperature sensor data. In some embodiments, the processing circuitry uses the airflow sensor data to calculate processed data indicative of the at least one characteristic of the airflow 101 of the testing device 400. The processing circuitry is then to determine the predicted ambient temperature proximate to a production device under the same conditions of the testing device 400. Processing circuitry may determine the predicted ambient temperature proximate to the production device based on airflow velocity and any one of: the temperature of the testing device, fluid pressure drop along the testing device, and airflow flux rate. In some embodiments, the fluid pressure drop along the testing device is determined by measuring the fluid pressure from each of the first air flow sensor 402 and the second air flow sensor 404 and calculating the difference between the respective measured fluid pressures. In some embodiments, the processing circuitry determines the predicted ambient temperature proximate to the production device based on previous iterations of data collection.

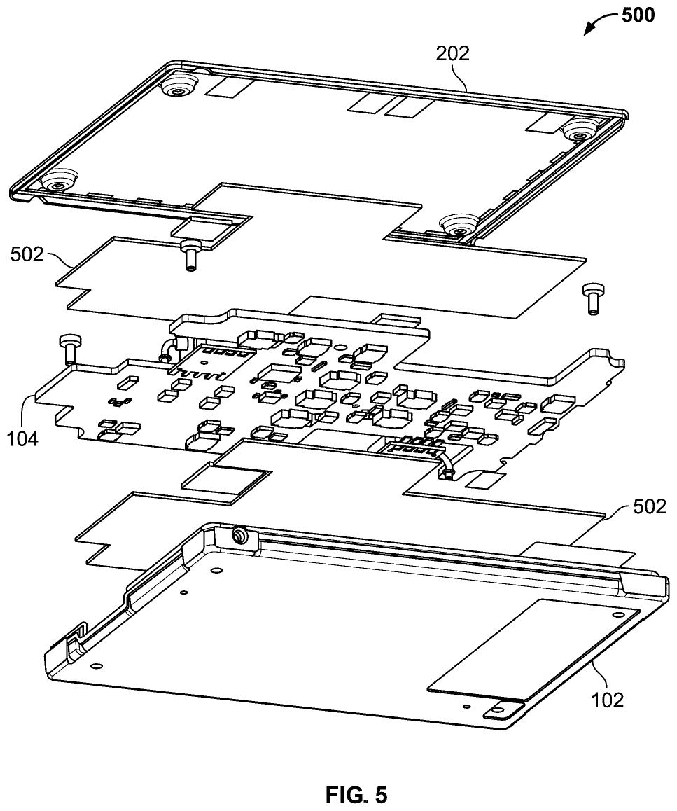

FIG. 5 shows an illustrative exploded view diagram of a testing package 500, in accordance with some embodiments of the present disclosure. In some embodiments, the testing package 500 includes at least one thermal interface material (TIM) layer 502 disposed between the circuitry 104 and at least one of: the top cover 102 or the bottom cover 202. In some embodiments, each TIM layer 502 is disposed in thermal contact with and coplanar to the heat-generating electrical components and either one of: the top cover 202 or the bottom cover 202. The respective TIM layers 502 are arranged in order for heat to transfer from the heat-generating electrical components to either of the top cover 102 or the bottom cover 202. The TIM layers aid the thermal dissipation of heat generated by the heat-generating electrical components throughout the testing package 500. The TIM layer 502 are composed of any thermally-conductive material to transfer heat from the heat-generating electrical elements of circuitry 104 to either of: the top cover 102 or bottom cover 202.

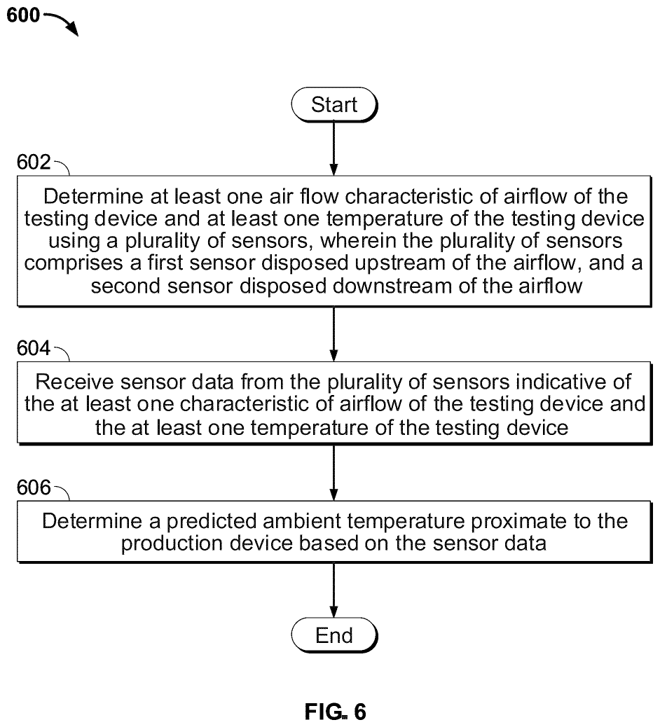

FIG. 6 shows a flowchart of illustrative steps for a process 600 for determining at least one airflow characteristic to be used for optimizing a device for temperature distribution, in accordance with some embodiments of the present disclosure. In some embodiments, the referenced testing device, airflow of the testing device, top cover, access point, circuitry, sensors, temperature sensors, airflow sensors, bottom cover, and heat-generating electrical components may be implemented as testing device 100, airflow 101 of the testing device, top cover 102, access point 103, circuitry 104, sensors 106, temperature sensors 108, airflow sensors 110, bottom cover 202, and heat-generating electrical components 204, respectively. In some embodiments, the process 600 can be modified by, for example, having steps rearranged, changed, added, and/or removed.

At step 602, determine at least one air flow characteristic of airflow of the testing device and at least one temperature of the testing device using a plurality of sensors, wherein the plurality of sensors includes a first sensor disposed upstream of the airflow, and a second sensor disposed downstream of the airflow. In some embodiments, the at least one temperature of the testing device is determined by the temperature sensors mounted onto the circuitry. In some embodiments, the at least one air flow characteristics of airflow of the testing device is determined by the at least two sensors (e.g., air flow sensors), a first sensor disposed upstream of the airflow and a second sensor disposed downstream of the airflow. In some embodiments, the at least one air flow characteristics include any one of the following: fluid pressure drop along the testing device, airflow velocity, and airflow flux rate.

At step 604, receive sensor data from the plurality of sensors indicative of the at least one characteristic of airflow of the testing device and the at least one temperature of the testing device. In some embodiments, sensor data includes temperature sensor data and airflow sensor data. In some embodiments, the processing circuitry receives sensor data from each of the sensors (e.g., temperature sensors and air flow sensors) via the circuitry on which the sensors are mounted. In some embodiments, the circuitry includes surface traces or internal electrical traces within the circuitry to transmit signals (e.g., sensor data) from each sensor to processing circuitry of circuitry for processing.

At step 606, determine a predicted ambient temperature proximate to the production device based on the sensor data. In some embodiments, processing circuitry of the circuitry determines the predicted ambient temperature proximate to the production device the testing device emulates based on air flow sensor data and the temperature sensor data. In some embodiments, processing circuitry calculates ambient air temperature proximate to the testing device. In some embodiments, the processing circuitry calculates a mean temperature of the received temperature sensor data. In other embodiments, the processing circuitry determines a maximum temperature value among the received temperature sensor data. In some embodiments, the processing circuitry uses the airflow sensor data to calculate processed data indicative of the at least one characteristic of the airflow of the testing device. The processing circuitry is then to determine the predicted ambient temperature proximate to a production device under the same conditions of the testing device. Processing circuitry may determine the predicted ambient temperature proximate to the production device based on airflow velocity and any one of: the temperature of the testing device, fluid pressure drop along the testing device, and airflow flux rate. In some embodiments, the processing circuitry determines the predicted ambient temperature proximate to the production device based on previous iterations of data collection. In some embodiments, the processing circuitry may repeat process 600 for any heat-generated by the heat-generating electrical components set by the processing circuitry.

The terms “an embodiment”, “embodiment”, “embodiments”, “the embodiment”, “the embodiments”, “one or more embodiments”, “some embodiments”, and “one embodiment” mean “one or more (but not all) embodiments” unless expressly specified otherwise.

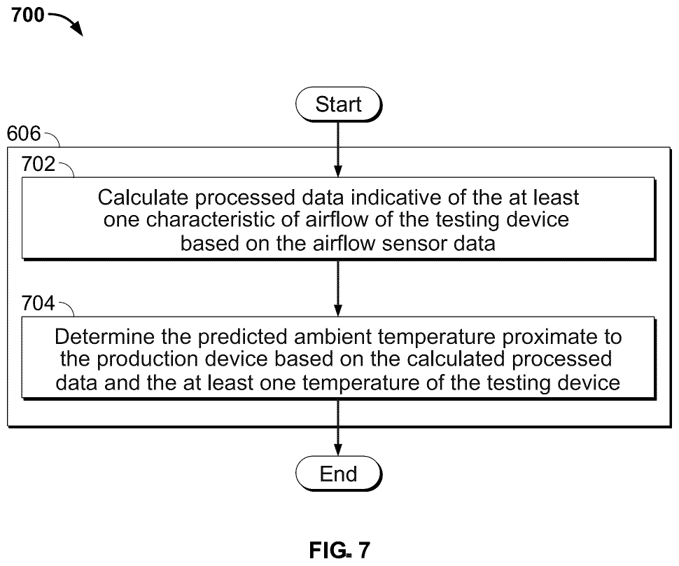

FIG. 7 shows a flowchart of illustrative steps of a subprocess 700 for determining a predicted ambient temperature proximate to the production device based on the sensor data, as shown at step 606 in FIG. 6, in accordance with some embodiments of the present disclosure. In some embodiments, the referenced testing device, airflow of the testing device, top cover, access point, circuitry, sensors, temperature sensors, airflow sensors, bottom cover, heat-generating electrical components, first airflow sensor and the second airflow sensor may be implemented as testing device 100, airflow 101 of the testing device, top cover 102, access point 103, circuitry 104, sensors 106, temperature sensors 108, airflow sensors 110, bottom cover 202, heat-generating electrical components 204, first airflow sensor 402 and second airflow sensor 404, respectively. In some embodiments, subprocess 700 can be modified by, for example, having steps rearranged, changed, added, and/or removed.

At step 702, the processing circuitry calculates processed data indicative of the at least one characteristic of the airflow of the testing device based on the received airflow sensor data. The processing circuitry may use the airflow sensor data received from the airflow sensors to calculate values of fluid pressure drop along the testing device, for example. In such an example, the fluid pressure drop along the testing device is calculated by determining the difference between a first fluid pressure determined at the first airflow sensor positioned upstream of the airflow and a second fluid pressure determined at the second airflow sensor positioned downstream of the airflow. The fluid pressure drop is at least one characteristic indicative of the airflow that may be calculated by the processing circuitry based on the airflow sensor data. In some embodiments, the processing circuitry may determine the airflow velocity or the airflow flux rate of the airflow of the testing device based on the airflow sensor data.

At step 704, the processing circuitry determines the predicted ambient temperature proximate to the production device based on the calculated processed data and the at least one temperature of the testing device. In some embodiments, processing circuitry calculates the predicted ambient temperature proximate to the production device based on the airflow sensor data and the temperature sensor data. The processing circuitry may determine the predicted ambient temperature proximate to the production device based on previous iterations of data collection, and therefore may correlate sensor data indicative of at least one characteristic of the airflow to a predicted ambient temperature proximate to the production device. In some embodiments the predicted ambient temperature proximate to the production device is determined without processing airflow sensor data into processed data indicative of at least one characteristic of the airflow. The processing circuitry determines the predicted ambient temperature proximate to the production device based on calculated processed data indicative of two of characteristics of the airflow of the testing device, including: fluid pressure drop along the testing device, airflow velocity, airflow flux rate, or ambient temperature.

For example, the processing circuitry may receive temperature sensor data indicating a testing device temperature of 55° C. and airflow sensor data which processed at step 702 to calculate a fluid pressure drop along the testing device to be 56 Pa. In some embodiments, the processing circuitry determines the corresponding airflow velocity of the airflow of the testing device to be 524 linear feet per minute (LFM) based on the fluid pressure drop. Based on previous iterations of data collection, the processing circuitry determines that a temperature rise which corresponds to 524 LFM is 20° C. Therefore, the processing circuitry calculates the predicted ambient temperature proximate to the production device emulated by the testing device to be 35° C.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments. Further, although process steps, method steps, algorithms or the like may be described in a sequential order, such processes, methods, and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments need not include the device itself.

At least certain operations that may have been illustrated in the figures show certain events occurring in a certain order. In alternative embodiments, certain operations may be performed in a different order, modified, or removed. Moreover, steps may be added to the above-described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to be limited to the precise forms disclosed. Many modifications and variations are possible in light of the above teaching.

What is claimed is:

1. A testing device comprising:
circuitry of a first form factor that corresponds to a second form factor of a production device, the circuitry comprising:
a plurality of heat-generating electrical components to simulate thermal generation of the production device;
a plurality of sensors to measure at least one characteristic of airflow of the testing device and to measure at least one temperature of the testing device, wherein the plurality of sensors comprises a first sensor disposed upstream of the airflow, and a second sensor disposed downstream of the airflow; and
processing circuitry to:
receive sensor data from the plurality of sensors indicative of the at least one characteristic of airflow of the testing device and the at least one temperature of the testing device, and
determine a predicted ambient temperature proximate to the production device based on the sensor data.

2. The testing device of claim 1, further comprising:
an enclosure comprising a top cover and a bottom cover; and
at least one thermal interface material (TIM) layer disposed between the circuitry and at least one of: the top cover or the bottom cover.

3. The testing device of claim 1, wherein the plurality of sensors comprises at least one temperature sensor.

4. The testing device of claim 1, wherein each of the first sensor and the second sensor is a fluid pressure sensor.

5. The testing device of claim 1, wherein the at least one characteristic of airflow comprises at least one of: fluid pressure drop along the testing device, airflow velocity, airflow flux rate, or ambient temperature.

6. The testing device of claim 1, further comprising power generation circuitry, wherein heat produced by the plurality of heat-generating electrical components is configurable by changing an amount of power provided to the plurality of heat-generating electrical components by the power generation circuitry.

7. The testing device of claim 1, further comprising at least one fan positioned proximate to the testing device to provide the airflow from the upstream to the downstream.

8. The testing device of claim 1, wherein the circuitry comprises a printed circuit board (PCB) on which the plurality of sensors and the plurality of heat-generating electrical components are mounted.

9. The testing device of claim 1, wherein the processing circuitry is further to:
determine an ambient temperature of testing device based on the sensor data; and
determine the predicted ambient temperature proximate to the production device based on the determined ambient temperature of the testing device.

10. The testing device of claim 1, wherein the first form factor of the circuitry is the same as the second form factor of the production device.

11. A method for using a testing device, the testing device comprising:
circuitry of a first form factor that corresponds to a second form factor of a production device, the circuitry comprising:
a plurality of heat-generating electrical components,
the method comprising:
determining at least one air flow characteristic of airflow of the testing device and at least one temperature of the testing device using a plurality sensors, wherein the plurality of sensors comprises a first sensor disposed upstream of the airflow, and a second sensor disposed downstream of the airflow;
receiving sensor data from the plurality of sensors indicative of the at least one characteristic of airflow of the testing device and the at least one temperature of the testing device; and
determining a predicted ambient temperature proximate to the production device based on the sensor data.

12. The method for using a testing device according to claim 11, wherein receiving data from the plurality of sensors comprises:
receiving sensor data from at least one temperature sensor.

13. The method for using a testing device according to claim 11, wherein determining at least one characteristic of airflow of the testing device using the plurality sensors, wherein the plurality of sensors comprise a first sensor disposed upstream of the airflow, and a second sensor disposed downstream of the airflow comprises:
determining at least one airflow characteristic of airflow of the testing device using the first sensor and the second sensor, wherein each of the first sensor and the second sensor is a fluid pressure sensor.

14. The method for using a testing device according to claim 11, wherein determining at least one characteristic of airflow of the testing device and the at least one temperature of the testing device comprises:
determining at least one of: fluid pressure drop along the testing device, airflow velocity, airflow flux rate, or ambient temperature.

15. The method for using a testing device according to claim 11, wherein the testing device further comprises power generation circuitry, the method further comprising:
changing heat produced by a plurality of heat-generating electrical components of the testing device by altering an amount of power provided to the plurality of heat-generating electrical components by the power generation circuitry.

16. The method for using a testing device according to claim 11, further comprising positioning a fan proximate to the testing device to provide the airflow from the upstream to the downstream.

17. The method for using a testing device according to claim 11, further comprising:
determining an ambient temperature of testing device based on the sensor data; and
determining the predicted ambient temperature proximate to the production device based on the determined ambient temperature of the testing device.

18. The method for using a testing device according to claim 11, wherein the first form factor of the circuitry is the same as the second form factor of the production device.

19. A production device comprising production circuitry arranged based on a predicted ambient temperature determined using a testing device, the testing device comprising:
test circuitry of a first form factor that corresponds to a second form factor of the production device, the test circuitry comprising:
a plurality of heat-generating electrical components to simulate thermal generation of the production device;
a plurality of sensors to measure at least one characteristic of airflow of the testing device and to measure at least one temperature of the testing device, wherein the plurality of sensors comprises a first sensor disposed upstream of the airflow, and a second sensor disposed downstream of the airflow; and
processing circuitry to:
receive sensor data from the plurality of sensors indicative of the at least one characteristic of airflow of the testing device and the at least one temperature of the testing device, and
determine the predicted ambient temperature proximate to the production device based on the sensor data.
